(19) United States
(12) Patent Application Publication
(10) Pub. No.: US 2026/0040649 A1
(43) Pub. Date: Feb. 5, 2026

(54) DIRECT BACKSIDE CONTACT TO 2D MATERIAL CHANNEL TRANSISTOR

(71) Applicant: International Business Machines Corporation, Armonk, NY (US)

(72) Inventors: Darsith Jayachandran, Menands, NY (US); Ruilong Xie, Niskayuna, NY (US); Chen Zhang, Santa Clara, CA (US); HUIMEI ZHOU, Albany, NY (US); Oleg Gluschenkov, Tannersville, NY (US)

(21) Appl. No.: 18/790,216

(22) Filed: Jul. 31, 2024

(51) Int. Cl. H01L 29/417; H01L 29/06; H01L 29/16; H01L 29/24; H01L 29/423; H01L 29/66; H01L 29/775; H01L 29/786

(52) U.S. Cl. CPC H10D 64/254; H10D 30/43; H10D 30/6735; H10D 30/6757; H10D 62/121; H10D 64/258; H10D 30/014; H10D 62/80; H10D 62/882

(57) ABSTRACT

A semiconductor integrated circuit (IC) device includes a first conductive source/drain region connected to a second conductive source/drain region by a plurality of active 2D material channels. The device further includes a conductive contact directly coupled to a bottom of the first conductive source/drain region, a liner directly coupled around an upper portion of the conductive contact, and a backside contact directly coupled to a lower portion of the conductive contact. The liner may reduce damage to the conductive contact that may occur during the formation of the backside contact.

### BACKGROUND

The embodiments of the present disclosure relate to fabrication methods and resulting structures for semiconductor integrated circuit (IC) devices. Two-dimensional (2D) materials are layered materials consisting of a single or multiple layers of generally planar atoms. The atoms in the layers are held together by saturated covalent bonds. Typically, the thickness of monolayer 2D materials is less than 1 nm. Owing to a typically inert and dangling-bond-free surface, the interface between different 2D material layers is nearly defect-free. Typically, the charge carrier mobility of 2D materials is relatively high.

### SUMMARY

In an embodiment of the disclosure, a semiconductor IC device is presented. The semiconductor IC device includes a first conductive source/drain region connected to a second conductive source/drain region by a plurality of active two dimensional (2D) material channels. The semiconductor IC device further includes a first conductive contact directly coupled to a bottom of the first conductive source/drain region. The semiconductor IC device further includes a first liner directly coupled around an upper portion of the first conductive contact. The semiconductor IC device further includes a backside contact directly coupled to a lower portion of the first conductive contact.

In an embodiment of the disclosure, a semiconductor IC device is presented. The semiconductor IC device includes a metallic source/drain region connected to a plurality of active two dimensional (2D) material channels. The semiconductor IC device further includes a metallic contact directly coupled to a bottom of the metallic source/drain region. The semiconductor IC device further includes a dielectric liner directly coupled around an upper portion of the metallic contact. The semiconductor IC device further includes a backside contact directly coupled to a lower portion of the metallic contact.

In another embodiment of the disclosure, a semiconductor integrated circuit (IC) device fabrication method is present. The method includes. In another embodiment of the present disclosure, a semiconductor IC device fabrication method is presented. The method includes separating a layered row into multiple layered stacks and thereby expose an underlying substrate structure. The method includes recessing the exposed substrate structure. The method includes depositing a dielectric liner upon respective sidewalls of the multiple layered stacks and upon the recessed substrate structure. The method includes forming a conductive contact upon the dielectric liner. A top surface of the conductive contact is substantially coplanar with a top surface of the dielectric liner. The method further includes forming a conductive source/drain region upon the top surface of the conductive contact and upon the top surface of the dielectric liner.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of an illustrative semiconductor IC device that includes a backside contact that is connected to a conductive source/drain region of a 2D material channel transistor, according to one or more embodiments of the disclosure.

FIG. 2 depicts a partial structure top-down view of an illustrative semiconductor IC device that is formed to include a backside contact that is connected to a conductive source/drain region of a 2D material channel transistor, according to one or more embodiments of the disclosure.

FIG. 3 through FIG. 12 depict various fabrication structure cross-section views of an illustrative semiconductor IC device that is formed to include a backside contact that is connected to a conductive source/drain region of a 2D material channel transistor, according to one or more embodiments of the disclosure.

FIG. 13 depicts a method of fabricating a semiconductor IC device formed to include a backside contact that is connected to a conductive source/drain region of a 2D material channel transistor, according to one or more embodiments of the disclosure.

### DETAILED DESCRIPTION

The embodiments of the present disclosure relate to fabrication methods and resulting structures for semiconductor IC devices. More specifically, the present disclosure relates to fabrication methods and resulting semiconductor integrated circuit (IC) devices that include a backside contact that is connected to a conductive source/drain region of a 2D material channel transistor. This scheme may be utilized to protect a lower conductive contact associated with the. conductive source/drain region during the formation of the backside contact. The embodiments of the present disclosure may limit damage to the lower conductive contact and/or to the conductive source/drain region that would otherwise occur by an etch that forms an opening of the backside contact.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a region in the semiconductor IC device, in which majority carriers are flowing into the channel. A drain is a region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanolayers, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material relative to a second material by a ratio of at least 5:1 or more, such as 10:1, 20:1, or the like.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanolayer, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active layers and sacrificial layers. The sacrificial layers are released from the active layers before the FET device is finalized. For n-type FETs, the active layers are historically silicon (Si) and the sacrificial layers are typically silicon germanium (SiGe). For p-type FETs, the active layers are historically SiGe and the sacrificial layers can be Si.

In some implementations of the present embodiments, the active layers may be 2D materials and the sacrificial layers are formed by a material with etch selectivity relative to the 2D material(s) of the active layers. Forming active layers, or channels, from 2D material(s) takes advantage of the relatively high charge carrier mobility of the 2D material(s). The source/drain regions associated with the channels may be formed of a conductive material, such as a metal, as opposed to a doped semiconductor material. In these instances, the conductive backside contact placeholder, such as a lower conductive contact, may be damaged when forming a direct backside contact associated therewith. As such, the embodiments of the present disclosure may reduce such damage to the lower conductive contact and/or to the conductive source/drain region that would otherwise occur.

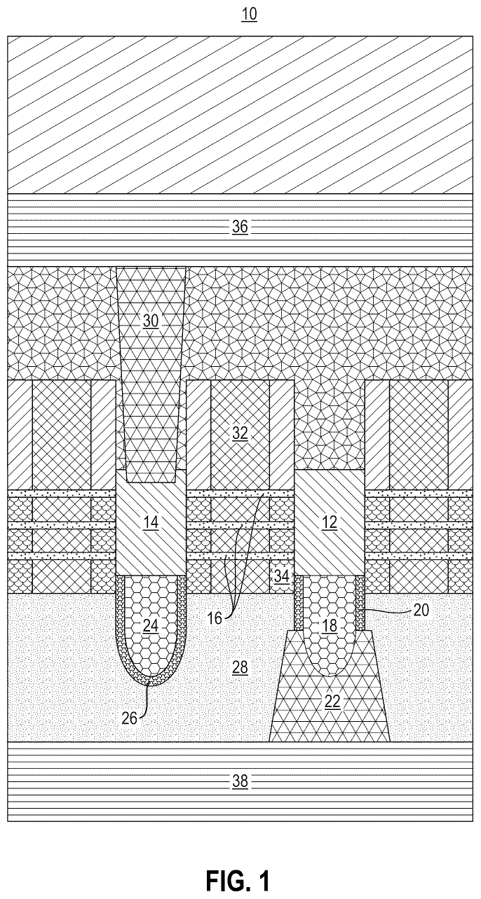

Referring now to the figures, FIG. 1 depicts a cross-sectional view of an illustrative semiconductor IC device 10 that includes a backside contact that is connected to a conductive source/drain region of a 2D material channel transistor. The semiconductor IC device 10 includes a first conductive source/drain region 12 connected to a second conductive source/drain region 14 by a plurality of active 2D material channels 16. The semiconductor IC device 10 further includes a first conductive contact 18 directly coupled to a bottom of the first conductive source/drain region 12. The semiconductor IC device 10 further includes a first liner 20 that is directly coupled around an upper portion of the first conductive contact 18. The semiconductor IC device 10 further includes a backside contact 22 directly coupled to a lower portion of the first conductive contact 18.

In an example, the semiconductor IC device 10 further includes a second conductive contact 24 directly coupled to a bottom of the second conductive source/drain region 14 and a second liner 26 directly coupled around a remaining perimeter of the second conductive contact 24.

In an example, the semiconductor IC device 10 further includes a backside interlayer dielectric (ILD) 28 directly coupled to the first liner 20, to the backside contact 22, and to the second liner 26.

In an example, the semiconductor IC device 10 further includes a frontside contact 30 directly coupled to the second source/drain region 14.

In an example, the semiconductor IC device 10 further includes a gate structure 32 directly coupled around the plurality of active 2D material channels 16.

In an example, the semiconductor IC device 10 further includes a bottom inner spacer 34 directly coupled to the gate structure 32, to the first conductive source/drain region 12, and to the first liner 20.

In an example, the semiconductor IC device 10 further includes a frontside back end of line network 36 that is connected to the frontside contact 30. In an example, the semiconductor IC device 10 further includes a backside back end of line network 38 that is connected to the backside contact 22.

In an example, a top surface of the first conductive contact 18 is between a bottom surface of a bottommost active 2D material channel of the plurality of active 2D material channels 16 and a top surface of the backside ILD 28.

In an example, the first conductive contact 18 is composed of a first conductive material and wherein the first conductive source/drain region 12 is composed of a second conductive material that is different from the first conductive material.

In an example, the first conductive contact 18 and the first conductive source/drain region 12 are composed of a substantially same conductive material and wherein there is an interfacial resistance between the first conductive contact 18 and the first conductive source/drain region 12.

In an example, respective ends of the plurality of active 2D material channels 16 are directly coupled to the first conductive source/drain region 12 and distal respective ends of the plurality of active 2D material channels 16 are directly coupled to the second conductive source/drain region 14.

In an example, wherein a top surface of the first liner 20 is substantially coplanar with a top surface of the first conductive contact 18. In an example, the lower portion of the first conductive contact 18 is inset within the backside contact 22.

In another embodiment of the present disclosure, another instance of the semiconductor IC device 10 is presented. The semiconductor IC device 10 includes a metallic source/drain region 12 that is connected to the plurality of active 2D material channels 16. The semiconductor IC device 10 further includes a metallic contact 18 directly coupled to a bottom of the metallic source/drain region 12. The semiconductor IC device 10 further includes a dielectric liner 20 directly coupled around an upper portion of the metallic contact 18. The semiconductor IC device 10 further includes the backside contact 22 directly coupled to a lower portion of the metallic contact 18.

In an example, the semiconductor IC device 10 further includes the backside ILD 28 directly coupled to the dielectric liner 20 and to the backside contact 22. In an example, the semiconductor IC device 10 further includes a gate structure 32 directly coupled around the plurality of active 2D material channels.

In an example, the semiconductor IC device 10 further includes the bottom inner spacer 34 directly coupled to the gate structure 32, to the first metallic source/drain region 12, and to the dielectric liner 20. In an example, the semiconductor IC device 10 further includes the backside back end of line network 38 that is connected to the backside contact 22.

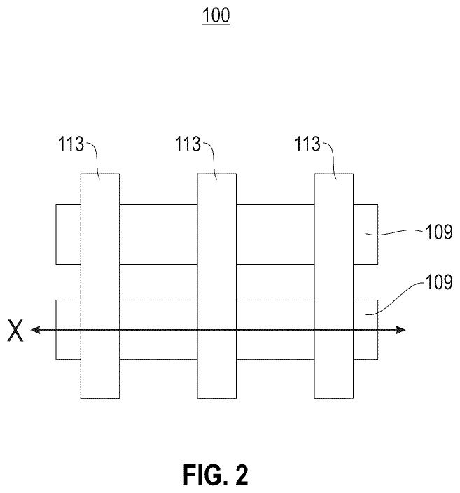

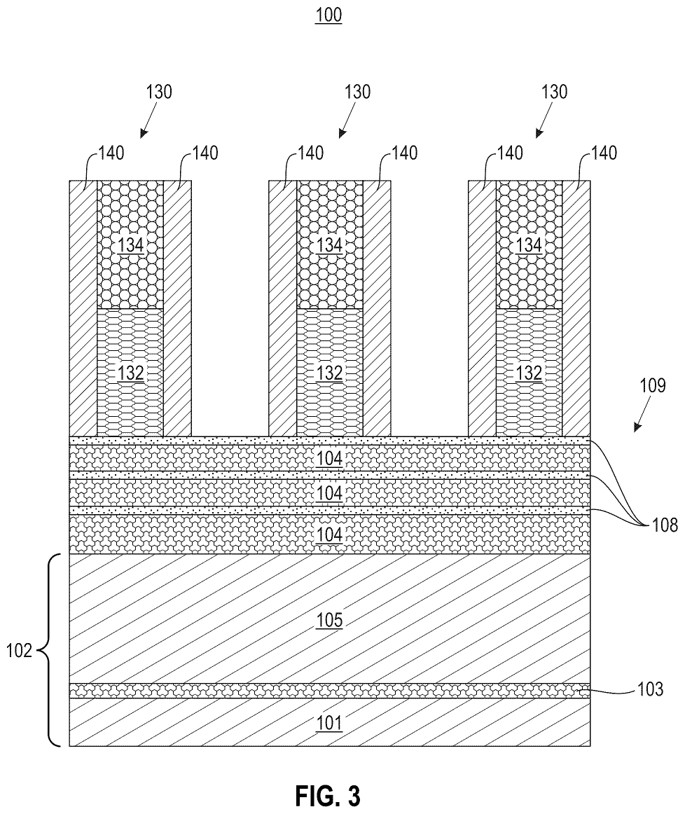

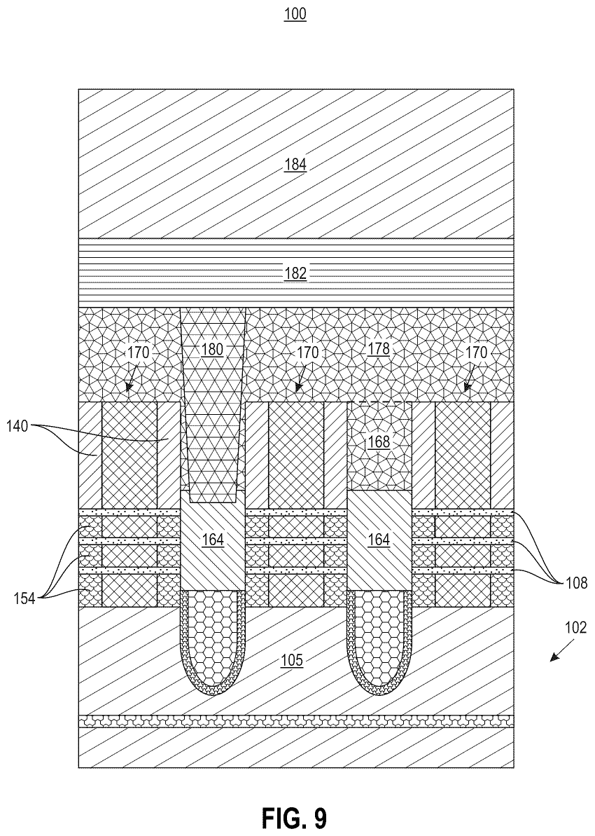

FIG. 2 depicts a partial structure top-down view of an illustrative semiconductor IC device 100 that is formed to include a backside contact that is connected to a conductive source/drain region of a 2D material channel transistor. As currently depicted, semiconductor IC device 100 includes layered rows 109 and gate structures 113 (such as sacrificial gate structures 130 depicted in FIG. 3 or replacement gate structures 170 depicted in FIG. 9).

FIG. 2 also depicts a cross-sectional plane X of the cross-sectional views of FIG. 3 through FIG. 12. The X cross-sectional plane is through a layered row 109 and across gate structures 113.

FIG. 3 depicts a fabrication structure cross-section view of the semiconductor IC device 100, according to one or more embodiments of the disclosure. At the present fabrication stage, semiconductor IC device 100 includes a substrate structure 102, one or more layered rows 109, one or more sacrificial gate structures 130, and gate spacers 140.

The illustrative semiconductor IC device 100 may be formed by initially providing or forming the substrate structure 102. The substrate structure 102 may be a bulk-semiconductor substrate. In one example, the bulk-semiconductor substrate may be a silicon-containing material. In another implementation, the substrate structure 102 includes an upper substrate 105, a lower substrate 101, and an etch stop layer 103 between the upper substrate 105 and the lower substrate 101. The upper substrate 105 and the lower substrate 101 may be comprised of any suitable semiconductor material(s), and the etch stop layer 103 may be a dielectric material with etch selectivity to one or both upper substrate 105 and/or the lower substrate 101. In one example, the etch stop layer 103 may be an oxide and the substrate structure 102 may be referred to as a buried oxide (BOX) substrate. In another example, the lower substrate 101 and the upper substrate 105 may be composed of Si. The etch stop layer 103 may be composed of Silicon Germanium (SiGe) and may be epitaxially grown from the top surface of lower substrate 101 and the upper substrate 105 may be epitaxially grown from the top surface of etch stop layer 103.

The illustrative semiconductor IC device 100 may be further formed by forming alternating active 2D material layers 108 and sacrificial layers 104 over the substrate structure 102. In certain examples, a bottommost sacrificial layer 104 is initially formed directly on an upper surface of the substrate structure 102. In other examples, certain layer(s) may be formed between the upper surface of the substrate structure 102 and the bottommost sacrificial layer 104. In an example, the bottommost sacrificial layer 104 may be formed by epitaxially growing a SiGe layer with a percentage of Ge, ranging from 20% to 60%, for example. Alternatively, the sacrificial layers 104 may be formed by depositing a SiGe layer with a percentage of Ge, ranging from 20% to 60%, for example. If the sacrificial layers 104 are not SiGe, the sacrificial layers 104 may be any suitable material that has etch selectivity relative to the active 2D material layers 108.

The active 2D material layers 108 are each composed of a substantially same or similar 2D material or are each composed or relatively different 2D materials. Exemplary 2D materials may include MoS₂, MoO₃, WS₂, WSe₂, MoTe₂, InSe, MoSe₂, Bi₂O₂Se, hBN, Graphene, or the like. In an example, the active 2D material layers 108 are composed of one or more 2D materials that are beneficial for p-type transistors (e.g., WSe₂, etc.). Alternatively, the active 2D material layers 108 are composed of one or more 2D materials that are beneficial for n-type transistors (e.g., MoS₂, etc.).

Generally, the 2D material layers are mono layers consisting of a single layer of atoms, respectively. The 2D material layer may be formed by deposition techniques, such as CVD, ALD, wet/dry transfer techniques, or the like. The 2D material layer may be a crystalline material consisting of a single layer of atoms. A thickness of the 2D material layer may be from, for example, 0.6 nm to 3 nm. For clarity, the plane of the single or each layer of atoms of each active 2D material layers 108 may be substantially horizontal or otherwise parallel to the top surface of the substrate structure 102.

In one example, each of the active 2D material layers 108 may be composed of a respective mono layer consisting of a single layer of atoms, respectively. In an alternative example, one or more of the active 2D material layers 108 may be composed of multiple mono layers each consisting of a single layer of atoms, respectively.

In some examples, the active 2D material layers 108 may be deposited using, for example, chemical vapor deposition (CVD), atmospheric pressure CVD (APCVD), low-pressure CVD (LPCVD) at a sub-atmospheric pressure, plasma enhanced CVD (PECVD), atomic layer CVD (ALCVD), or combinations thereof. Further, the active 2D material layers 108 may be formed by growing or otherwise forming the 2D material layer(s) upon a growth substrate and transferring the 2D material layer(s) upon the target surface.

In an implementation, the active 2D material layers 108 and sacrificial layers 104 may be fabricated by forming each layer until the desired number of layers are formed. The desired number and sequence of the active 2D material layers 108 and sacrificial layers 104 can be provided to achieve a desired alternating layer geometry.

Further, in the depicted fabrication stage, active 2D material layers 108 and sacrificial layers 104 may be patterned into layered rows 109. The one or more layered rows 109 may be formed by lithography and etching techniques. In such process(es), a mask (not shown) may be applied to the top surface of the topmost active 2D material layers 108 or sacrificial layer 104 and patterned. Openings in the patterned mask may sequentially expose the portion(s) of the underlying layers that are to be removed while other protected portions of layers may be protected and retained. A etch may remove the unprotected layers while the protected layers may form the layered rows 109.

In the depicted fabrication stage, sacrificial gate structures 130 may be formed. The sacrificial gate structures 130 may include a sacrificial gate liner (not shown), a sacrificial gate 132, and a sacrificial gate cap 134. The sacrificial gate structures 130 may be formed by initially depositing a sacrificial gate liner (e.g., a dielectric, oxide, or the like) upon the substrate structure 102 and upon and around the one or more layered rows 109. The sacrificial gate structures 130 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more layered rows 109. The sacrificial gate structures 130 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 130 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 132, and the sacrificial gate cap 134, respectively, of each of the one or more sacrificial gate structures 130.

In the depicted fabrication stages, gate spacers 140 may be formed. The gate spacers 140 may be formed by a conformal deposition of a dielectric material, such as silicon nitride, SiBCN, SiNC, SiN, SiCO, SiNOC, or a combination thereof, or the like, upon substrate structure 102, upon around the one or more sacrificial gate structures 130, and upon and around the one or more layered rows 109. Subsequently, undesired portions of dielectric material may be removed while desired portions the dielectric material may be retained to thereby form the gate spacers 140 located generally upon the sidewalls of the sacrificial gate structures 130.

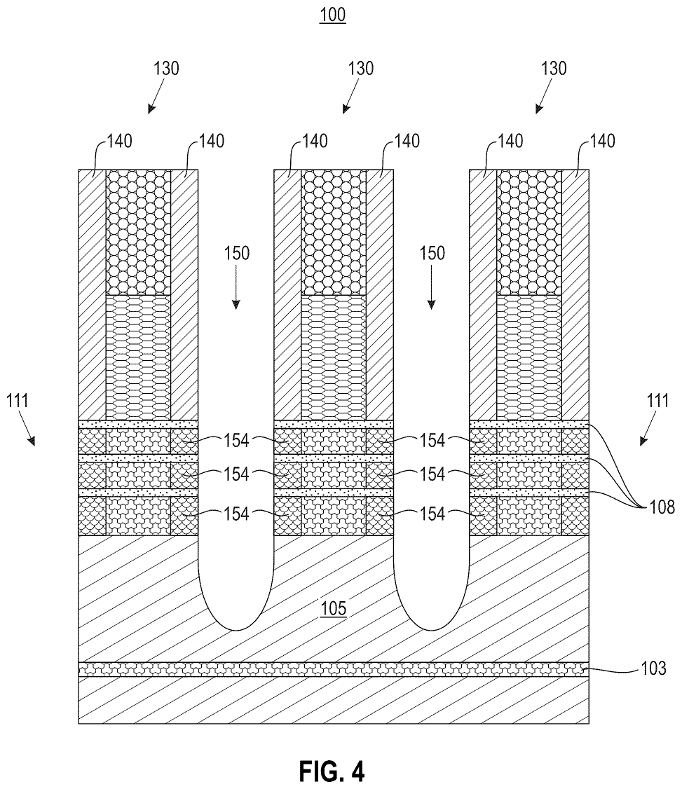

FIG. 4 depicts a fabrication structure cross-section view of the semiconductor IC device 100, according to one or more embodiments of the disclosure. At the present fabrication stage, layered rows 109 may be separated, sacrificial layers 104 are laterally indented, and inner spacers 154 may be formed.

At the present fabrication stage, one or more recesses 150 may be formed by removing portions of the layered rows 109 that are between gate spacers 140 of adjacent or neighboring sacrificial gate structures 130.

The recesses 150 may resultantly separate a single layered row 109 into multiple layered stacks 111 each located underneath a portion of respective sacrificial gate structure 130 and associated gate spacers 140. The one or more recesses 150 may be formed to a depth within the top substrate 105 or generally above the etch stop layer 103. The undesired portions of the active 2D material layers 108 and the sacrificial layers 104 may be removed by etching or other subtractive removal techniques. As the gate spacers 140 and the sacrificial gate structures 130 may be utilized to protect the underlying portions of the active 2D material layers 108 and the sacrificial layers 104, respective sidewalls of the layered stacks 111 may be substantially vertical and substantially coplanar with the outer sidewalls of the gate spacers 140, there above.

As used herein, “substantially vertical” sidewalls deviate from a direction perpendicular to a major surface (e.g., top horizontal surface, etc.) of the substrate structure 102 by less than 5°, e.g., 0°, 1°, 2°, 3°, 4°, or 5°, including ranges between any of the foregoing values.

At the present fabrication stage, the sacrificial layers 104 may be laterally indented by a reactive ion etch (RIE) process, which can horizontally remove portions of the sacrificial layers 104. The horizontal depth of the lateral indents may be chosen to set a length for a respective replacement gate structure that is formed in place of a removed sacrificial gate structure 130. When the sacrificial layers 104 are composed of SiGe, the directional RIE can use a boron-based chemistry or a chlorine-based chemistry, for example, which recesses or removes the exposed end portions of sacrificial layers 104 selective to the active 2D material layers 108. In alternative implementations, when sacrificial layers 104 are not SiGe, the directional etch of the sacrificial layers 104 may generally be selective to the active 2D material layers 108, to the gate spacers 140, and/or to the substrate structure 102.

At the present fabrication stage, a respective inner spacer 154 may be formed within each indent. The one or more inner spacers 154 can be formed by ALD or CVD or any other suitable deposition technique that deposits a dielectric material within the indent(s), thereby forming the inner spacer(s) 154. In some examples, the inner spacers 154 are composed of a low-x dielectric material (a material with a lower dielectric constant relative to SiO₂), SiN, SiO, SiBCN, SiOCN, SiCO, etc. or any other suitable dielectric material. In certain implementations, after the formation of the inner spacers 154, a directional etch process is performed to create substantially vertical sidewalls of the inner spacers 154 that are coplanar with the substantially vertical sidewalls of the of the gate spacers 140, or the like.

In some implementations, the recesses 150 may be deepened within the substrate structure 102 between neighboring sacrificial gate structures 130. The substrate structure 102 may be removed by an etch process that may be controlled so that the well surface of the recesses 150 stops above the etch stop layer 103 of the substrate structure 102. This well within the substrate structure 102 may be referred to as a backside contact placeholder opening and may be formed to allow for adequate volume of so that a conductive contact may be formed therein. For clarity, a respective backside contact placeholder opening may be formed in each location in which a conductive source/drain region is to be formed there above.

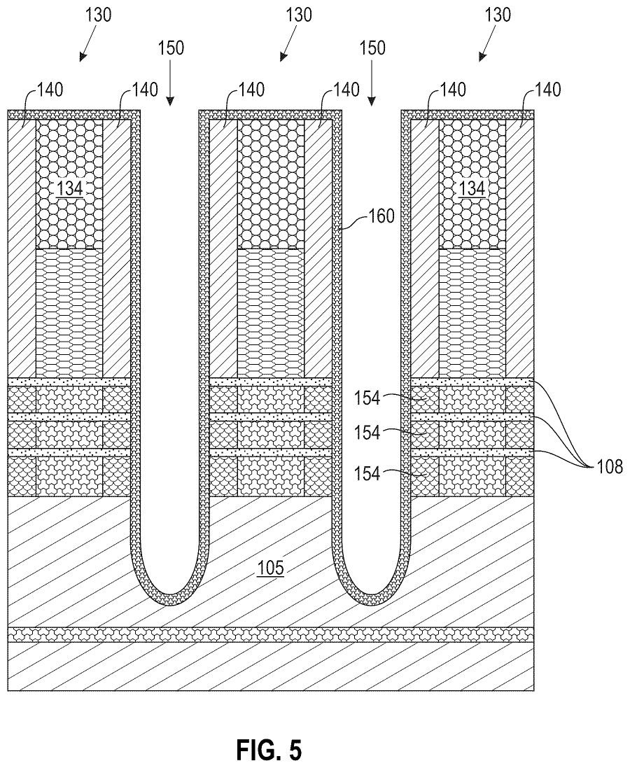

FIG. 5 depicts a fabrication structure cross-section view of the semiconductor IC device 100, according to one or more embodiments of the disclosure. At the present fabrication stage, a liner 160 layer may be formed.

The liner 160 layer may be formed by a conformal deposition of a dielectric material, such as silicon oxide, silicon nitride, or a combination thereof, that has etch selectivity to the material of gate spacers 140, inner spacers 154, active 2D material layers 108, etc. The dielectric may be deposited as a blanket layer upon the sacrificial gate cap 134, gate spacers 140, active 2D material layers 108, inner spacers 154, and substrate structure 102, and the like, upon the sacrificial gate structures 130 and within the recesses 150, respectively. In an example, the liner 160 may be composed of a material that has imperfect etch selectivity relative to the material of the upper substrate 105.

As used herein, the terms “imperfectly selective”, “imperfect selectively”, or the like in reference to a material removal or etch process denotes that the rate of material removal ratios of two materials is less than a selective etch as defined herein. For example, the rate of material removal of the upper substrate 105 by an imperfect selective etch is greater than the rate of removal of the liner 160 by a ratio that is less than 5:1, such as 3:1, 2:1, 1.1:1, or the like.

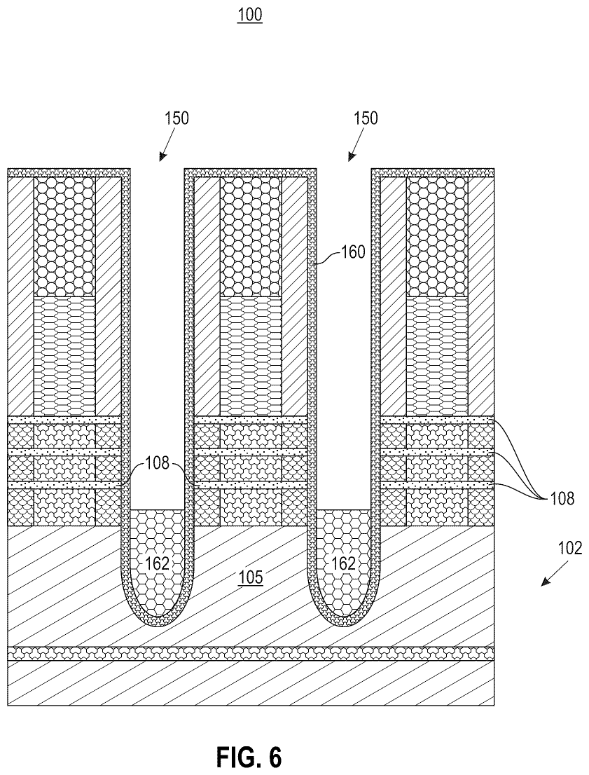

FIG. 6 depicts a fabrication structure cross-section view of the semiconductor IC device 100, according to one or more embodiments of the disclosure. At the present fabrication stage, a conductive contact 162 may be formed upon the liner 160 layer within a respective recess 150.

The conductive contact 162 may be formed by depositing conductive material, such as one or more metals, metal alloys, or the like, upon the liner 160 layer from a frontside of the semiconductor IC device 100. In an example, the conductive material of the conductive contact 162 may overfill the recesses 150 and may be subsequently recessed by an etch or other subtractive removal technique. Subsequently, a top surface of the conductive contact 162 may be below the bottom surface of the bottommost active 2D material layers 108. The top surface of the conductive contact 162 may also be above a top surface of the substrate structure 102 (e.g., the top surface of the upper substrate 105).

In an example, conductive contact 162 may be formed by depositing a conductive liner, such as Ni, NiPt or Ti, etc. upon the liner 160, depositing an conductive adhesion liner, such as TiN, TaN, etc. upon the liner, and by depositing a conductive fill, such as Al, Ru, W, Co, Cu, etc. upon the conductive adhesion liner. In alternative examples, conductive contact 162 may be formed by depositing solely a metal or other conductor material directly upon the liner 160 layer.

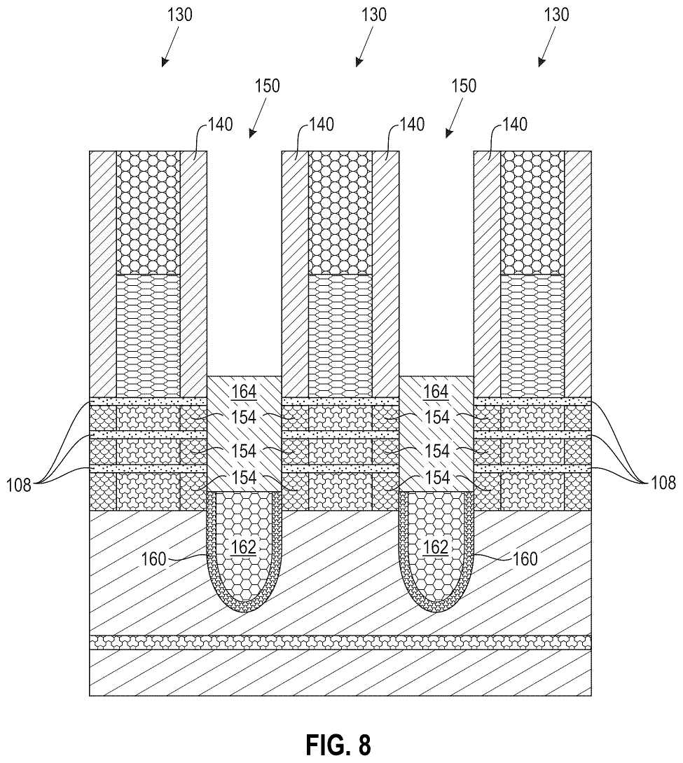

The etch back may remove excess portions of the liner, the adhesion liner, and/or the conductive fill so the top surface of the conductive contact 162 is below the bottom surface of the bottommost active 2D material layers 108, which may generally allow for or provide for the bottom bottommost active 2D material layers 108 to be in contact with the conductive source/drain region 164, as depicted in FIG. 8.

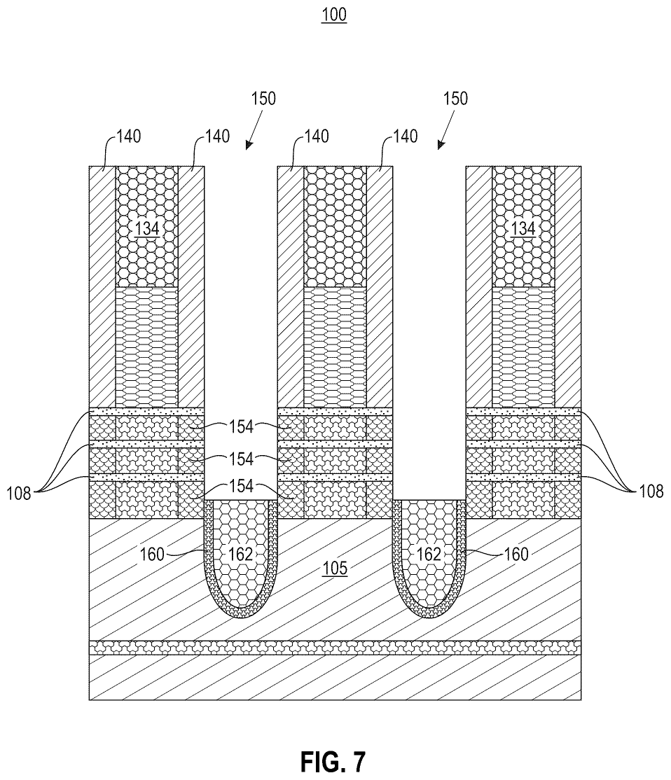

FIG. 7 depicts a fabrication structure cross-section view of the semiconductor IC device 100, according to one or more embodiments of the disclosure. At the present fabrication stage, the liner 160 layer is partially recessed. For example, the portions of the liner 160 layer that exists above the conductive contact 162 may be removed. The liner 160 layer may be partially removed by an etch process that removes the exposed portions of the liner 160 layer selective to the active 2D material layers 108, to the gate spacers 140, to the inner spacers 154, to the gate cap 134, and to the conductive contact 162.

In an example, the undesired portions of liner 160 layer may be removed from within the recesses 150 while desired portions of the liner 160 layer may be retained and may form the associated liner 160. In one example, the portions of the liner 160 below the top surface of the conductive contact 162 may be retained to form the liner 160. In an example, the top surface of the conductive contact 162 may be substantially coplanar with the top surface(s) of the associated liner 160 therearound.

FIG. 8 depicts a fabrication structure cross-section view of the semiconductor IC device 100, according to one or more embodiments of the disclosure. At the present fabrication stage, a respective conductive source/drain region 164 may be formed above conductive contact 162 within recess 150.

The conductive source/drain regions 164 may be formed by depositing a conductive material, such as a metal, within the recesses 150 upon the conductive contact 162 and liner 160 between adjacent sacrificial gate structures 130. A subsequent etch back may remove undesired conductive material and partially reform recesses 150. A top surface of the conductive source/drain regions 164 may be above the top surface of the topmost of the active 2D material layer 108. Each conductive source/drain region 164 may form either a source or a drain, respectively, of a respective transistor a transistor and is connected to respective end surfaces of the active 2D material layer 108 of the transistor. For example, as depicted, the active 2D material layers 108 may serve as the channels between the conductive source/drain regions 164 of the transistor. In an example, the source/drain region 164 may be formed directly upon respective sidewalls of the inner spacers 154 exposed to the recesses 150. The inner spacers 154 may separate and/or adequately electrically isolate the gate structure (e.g., the replacement gate structure 170 depicted in FIG. 9) from the conductive source/drain regions 164.

As used herein, a “source/drain” region or “S/D” region can be a source region or a drain region depending on subsequent wiring and application of voltage thereto during operation of the applicable transistor.

FIG. 9 depicts cross-sectional views of the semiconductor IC device 100 after fabrication operations, in accordance with embodiments of the present disclosure. In the depicted fabrication stages, frontside ILD 168 may be formed, sacrificial gate structures 130 (shown in FIG. 8) may be removed, replacement gate structures 170 may be formed in place thereof, frontside ILD 178 may be formed, one or more frontside contacts 180 may be formed, a frontside back end of the line (BEOL) network 182 may be formed, and a carrier wafer 184 may be bonded thereto.

The frontside ILD 168 may be formed by depositing a blanket dielectric material over the S/D region(s) 164, over the STI regions, over the sacrificial gate structures 130, over the gate spacers 140, and the like. The frontside ILD 168 can be composed any suitable dielectric material, such as, for example, porous silicates, carbon doped oxides, silicon dioxides, silicon nitrides, silicon oxynitrides, or other dielectric materials. A planarization process, such as a CMP, may be performed to remove excess frontside ILD 168 material and to remove the sacrificial gate cap 134 of the sacrificial gate structures 130, thereby exposing the sacrificial gate 132 thereunder.

The sacrificial gate structures 130 may be removed (and are therefore not presently depicted) and replacement gate structures 170 may be formed in place thereof. The sacrificial gate structures 130 may be removed by initially removing the sacrificial gate 132 and sacrificial gate oxide by a removal technique, such as one or more series of etches. For example, such removal may be accomplished by a wet chemical etching process in which one or more chemical etchants are used to remove the sacrificial gate 132 and sacrificial gate oxide of the sacrificial gate structures 130 selective to the active 2D material layers 108, inner spacers 154, gate spacers 140, STI regions 120, or the like.

Next, or simultaneously, the active 2D material layers 108 may be released by removing the sacrificial layers 104. The sacrificial layers 104 may be removed by a removal technique, such as one or more series of etches. After the removal of sacrificial layers 104, void spaces may be formed above and/or below the active 2D material layers 108.

The replacement gate structure 170 may be formed in place of the removed sacrificial gate structures 130 around the released active 2D material layers 108, upon the substrate structure 102, etc. The replacement gate structure(s) 170 may be formed by forming an interfacial layer on the gate spacers 140, on the active 2D material layers 108, on the substrate structure 102, on the inner spacers 154, etc. that are interior to and/or upon the respective surfaces interior to the opening created by the removal of the sacrificial gate structure 130 and the releasing of the active 2D material layers 108.

The replacement gate structure(s) 170 may be further formed by depositing a high-x layer to cover the exposed surfaces of the interfacial layer. A high-x material is a material with a higher dielectric constant than that of SiO₂. The high-x layer can include a single layer or multiple layers, such as metal layer, liner layer, wetting layer, and adhesion layer. The replacement gate structure(s) 170 may be further formed by depositing a work function (WF) gate upon the high-x layer. The WF gate can be comprised of a conductor or metal. In general, the WF gate sets the threshold voltage (Vt) of the device. The high-x layer may separate the WF gate from the channel (i.e., active 2D material layers 108). Other metals that may be desired to further fine tune the effective work function (eWF) and/or to achieve a desired resistance value associated with current flow through the gate in the direction parallel to the plane of the active 2D material layers 108.

The replacement gate structure(s) 170 may be further formed by depositing a conductive gate upon the WF gate. In an example, when none of the previous replacement gate material(s) are utilized in the replacement gate structures, the conductive gate may be formed upon the same or similar surfaces as those upon which the interfacial layer, described above, may be formed. In other examples, when one or more of the interfacial layer, the high-x layer, the WF gate, or the like, are or are not utilized in the replacement gate structures 170, the conductive gate may be formed upon the most recent structural formation thereof.

The conductive gate can be comprised of a conductor material and/or metal, such as but not limited to, e.g., tungsten, aluminum, ruthenium, rhodium, cobalt, copper, tantalum, titanium, or the like. After the replacement gate structure 170 formation, the top surface of the semiconductor IC device 100 may be planarized by a planarization technique such as a CMP, mechanical grinding process, or the like.

The frontside contact frontside ILD 178 may be formed upon respective top surfaces of replacement gate structure(s)170, frontside ILD 168, and gate spacers 140. The frontside contact frontside ILD 178 may be formed by depositing a dielectric material, such as, for example, porous silicates, carbon doped oxides, silicon dioxides, silicon nitrides, silicon oxynitrides, or other dielectric materials. The material of the frontside contact frontside ILD 178 may be the same as the material of the frontside ILD 168, as depicted. Alternatively, the frontside contact frontside ILD 178 may be a relatively different dielectric material.

The frontside contacts 180 may be formed by patterning respective frontside contact openings within the frontside ILD 168, the frontside contact frontside ILD 178, respectively, from the frontside (i.e., from above the semiconductor IC device 100, as depicted, downward to respective structures thereof). The frontside contacts 180 may be in direct or indirect physical and electrical contact with respective material(s) of one or more regions of the semiconductor IC device 100.

The frontside contact(s) 180 may be formed by depositing conductive material such as metal into the respective frontside contact opening(s). In an example, frontside contact(s) 180 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contact(s) 180 are fabricated in middle-of-line (MOL) fabrication operations and may be illustrations of MOL frontside contacts.

Further in the depicted fabrication stages, a frontside back end of line (BEOL) network 182 may be formed and a carrier wafer 184 may be bonded thereto. In the semiconductor IC device fabrication industry, there are three sections referred to in a build: front-end-of-line (FEOL), BEOL, and the section that connects those two together, the MOL. The FEOL is made up of devices, e.g., transistors, the BEOL is made up of interconnects and wiring, and the MOL includes interconnects between the FEOL and BEOL and material to prevent the diffusion of BEOL conductive material(s) to the FEOL devices.

The BEOL section is the portion of IC fabrication where the individual devices (e.g., transistors, capacitors, resistors, etc.) become interconnected with wiring on the semiconductor IC device, e.g., the metallization layer or layers of a wafer. The BEOL section includes contacts, insulating layers (dielectrics), metal levels, and bonding sites for chip-to-package connections. In the BEOL section, part of the fabrication stage contacts (pads), interconnect wires, vias and dielectric structures are formed. For modern IC processes, more than one metal layers may be added in the BEOL section.

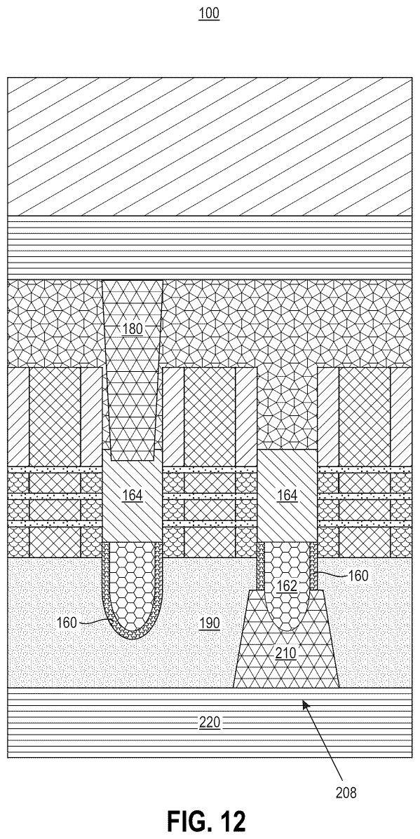

In the present example, there are multiple BEOL levels each on opposites sides of the semiconductor IC device 100. First, a frontside BEOL network 182 is formed on the frontside of the semiconductor device 100. Subsequently, a backside BEOL network 220, as depicted in FIG. 12, is formed.

In the depicted example, the frontside BEOL network 182 is formed over the frontside contact frontside ILD 178 and upon the frontside contacts 180. Respective wires within the frontside BEOL network 182 may be electrically connected to the one or more S/D regions 164, to the one or more replacement gate structure(s) 170, or the like, by a respective frontside contact(s) 180. For example, respective wire(s) within the frontside BEOL network 182 may be electrically connected to an appropriate S/D region 164 by a frontside contact 180 and another and different group of respective wire(s) within the frontside BEOL network 182 may be electrically connected to an appropriate replacement gate structure 170 by a different frontside contact 180, etc.

The frontside BEOL network 182 can include one or more interconnect dielectric material layers (including one of the dielectric materials mentioned above for the frontside ILD 168) and contains conductive wires (the conductive wires can be composed of any electrically conductive material, metal, electrically conductive metal alloy, or the like) embedded therein. In some embodiments, the frontside conductive wires within the frontside BEOL network 182 are composed of Cu. The frontside BEOL network 182 can include “x” numbers of frontside metal levels, wherein “x” is an integer starting from 1. The frontside BEOL network 182 may further contain conductive pads that are connected to one or more of the conductive wires and may be used to connect the semiconductor IC device 100 to an external and/or higher-level structure, such as a chip carrier, motherboard, or the like.

The illustrated semiconductor IC device 100 may be further fabricated by bonding carrier wafer 184 to the frontside BEOL network 182. The carrier wafer 184 can include one of the semiconductor materials mentioned above for the semiconductor structure and the carrier wafer 184 may be attached to the semiconductor IC device 100 by a wafer-to-wafer bonding technique.

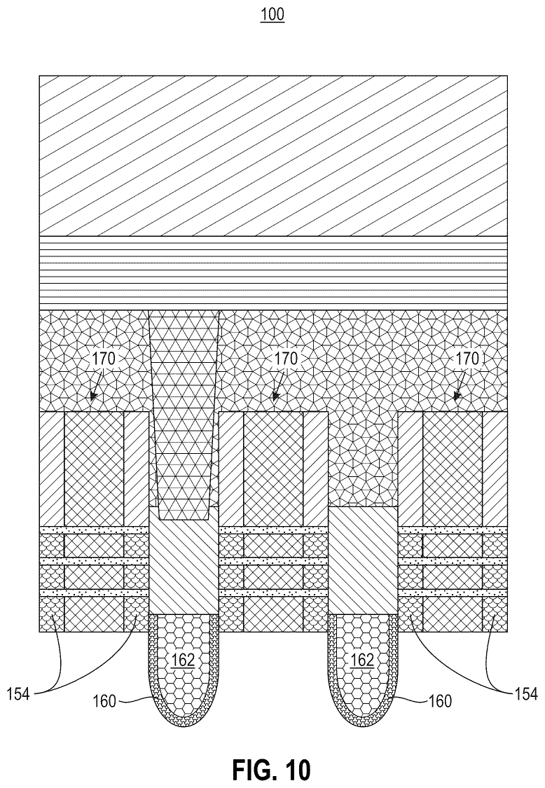

FIG. 10 depicts cross-sectional views of the semiconductor IC device 100 after fabrication operations, in accordance with embodiments of the present disclosure. In the depicted fabrication stages, substrate structure 102 may be recessed.

The substrate structure 102 may be recessed by flipping the semiconductor IC device 100 and removing the substrate structure 102 by appropriate substrative removal techniques, such as one or more series of etches. The one or more etches may be timed or otherwise controlled to remove the material of substrate structure 102 selective to the replacement gate structures 170, to the inner spacers 154, and to the liners 160, or the like.

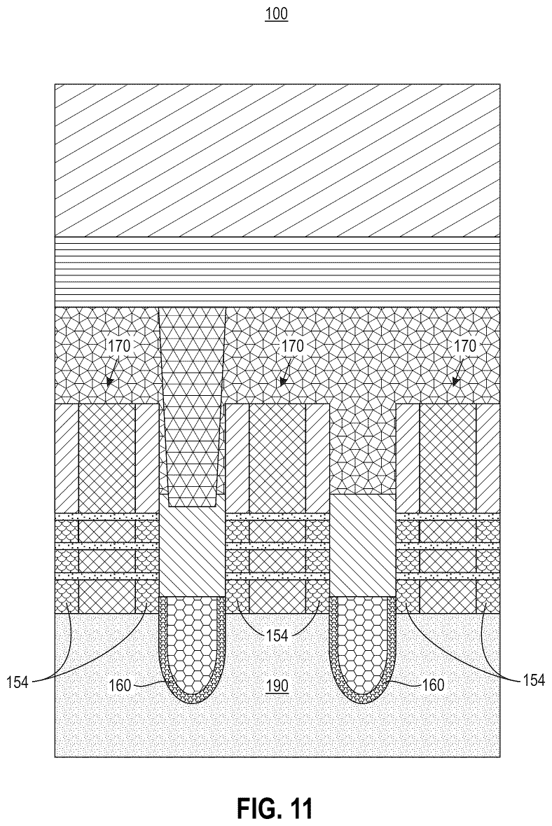

FIG. 11 depicts cross-sectional views of the semiconductor IC device 100 after fabrication operations, in accordance with embodiments of the present disclosure. In the depicted fabrication stages, a backside ILD 190 may be formed.

The backside ILD 190 may be formed upon the backside of the semiconductor IC device 100 (i.e., as depicted from below the semiconductor IC device 100 upward). The backside ILD 190 may be formed directly upon the backside of inner spacers 154, the backside of the replacement gate structures 170, and upon the exposed surfaces of liners 160. The backside ILD 190 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 190 can be utilized. The backside ILD 190 can be formed using, for example, CVD, PECVD, ALD, flowable CVD, spin-on dielectrics, or PVD.

In an example, as depicted, the material of the backside ILD 190 may be the same material as the frontside ILD 168. In alternative examples, the material of the backside ILD 190 may be chosen to achieve a predetermined electrical isolation metric that the dielectric material of frontside ILD 168 could not achieve, if utilized. For example, frontside ILD 168 may be silicon dioxide and the backside ILD 190 may be a low-x dielectric material.

FIG. 11 depicts cross-sectional views of the semiconductor IC device 100 after fabrication operations, in accordance with embodiments of the present disclosure. In the depicted fabrication stages, one or more backside contact 210 may be formed and a backside BEOL network 220 may be formed.

The one or more backside contacts may be formed by initially forming associated backside contact openings 208 by lithography and etch process(es). In such process(es), a mask (not shown) may be applied to the backside of the semiconductor IC device 100 and patterned. Openings in the patterned mask may sequentially expose the portion(s) of the underlying backside ILD 190 that are to be removed while other protected portions of semiconductor IC device 100 may be protected and retained.

The backside contact opening 208 may be located in line with a particular conductive contact 162 that is associated with a respective S/D region 164 in which a frontside contact 180 is not connected. A backside contact opening 208 may be formed to expose the associated conductive contact 162 there above by removing the associated portion of the backside ILD 190 and the associated liner 160 that is around a bottom or lower portion of the conductive contact 162. Such removal may remove the backside ILD 190 material with imperfect etch selectivity with respect to the liner 160. As such, the imperfect etch of the liner 160 may achieve a well or depth of the backside contact opening 208 such that the well surface of the backside contact opening 208 (e.g., the top surface of the backside contact 210) is above the bottom surface conductive contact 162 while substantially leaving the conductive contact 162 intact. In this manner, the conductive contact 162 may be largely protected during the formation of the backside contact opening 208.

Generally, the backside contact opening 208 may be formed to expose conductive contact 162. That is, the backside contact opening 208 may remove a portion of the liner 160 that is around the lower portion of the conductive contact 162. The backside contact openings 208 may have a horizontal dimension greater than a similar horizontal dimension of the associated conductive contact 162 there above, as depicted.

The backside contact 210 may be further formed within a respective backside contact opening 208 against the associated conductive contact 162 and against the associated liner 160 by depositing conductive material, such as metal, therein. In an example, multiple backside contacts 210 may be simultaneously formed by depositing a liner, such as Ni, NiPt or Ti, etc. onto the backside of semiconductor IC device 100 and into the backside contact openings 208, depositing an adhesion liner, such as TiN, TaN, etc. upon the liner, and by depositing a conductive fill, such as Al, Ru, W, Co, Cu, etc. upon the adhesion liner.

For clarity, because backside contact 210 may be formed within the backside contact opening 208 against or otherwise around the exposed portion of the associated conductive contact 162, the conductive contact 162 may be inset within the backside contact 210. For example, the lower portion of first conductive contact 162 that is below the liner 160 may be inset within the backside contact 210.

Subsequently, a planarization process, such as a CMP, may expose a bottom surface of the backside ILD 190 and a bottom surface of the backside contacts 210. As a result, the respective bottom surfaces of backside contacts 210 and backside ILD 190 may be substantially horizontal and/or substantially coplanar.

In the depicted fabrication stage, the backside BEOL network 220 may be formed. The backside BEOL network 220, such as a backside power distribution network (BSPDN) may be formed upon the backside contacts 210, upon the backside ILD 190, etc. The backside BEOL network 220 may include signal wires for signal routing and power wires for providing power potential (e.g., VDD, VSS, etc.). The backside BEOL network 220 may allow for the distribution of power wires and signal wires between both the frontside and backside of the semiconductor IC device. The backside BEOL network 220 may further allow for the full or partial decoupling of signal routing and/or power routing and/or allows for dividing or splitting power wires and/or signal wires between both the frontside and backside of the semiconductor IC device 100. By incorporating the backside BEOL network 220, wire and contact routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 220 may be electrically connected to the one or more S/D regions 164 by way of a particular backside contact 210. For example, a first backside wire within the backside BEOL network 220 may be electrically connected the backside contact 210, or the like.

The backside BEOL network 220 can include one or more interconnect dielectric material layers and contains backside conductive wires and/or interconnects, such as VIAs, embedded therein. In some embodiments, the backside wires within the backside BEOL network 220 are composed of Cu. The backside BEOL network 220 can include “x” numbers of backside metal levels, wherein “x” is an integer starting from 1. If not included in frontside BEOL network 182, backside BEOL network 220 may further contain conductive pads that are connected to one or more of the backside metal wires and may be used to connect the semiconductor IC device 100 to the external and/or higher-level structure.

In an example, signal routing and power routing is effectively split between the frontside BEOL network 182 and the backside BEOL network 220. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

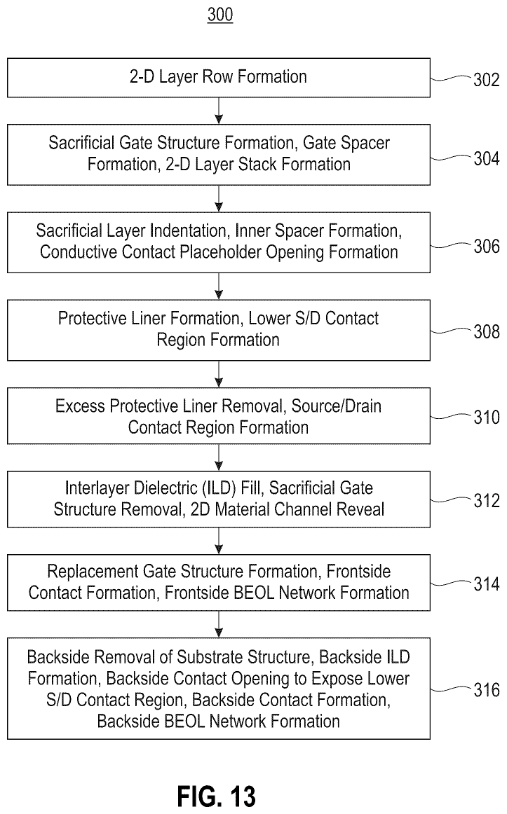

FIG. 13 depicts a flow diagram illustrating a method 300 to fabricate a semiconductor IC device, such as semiconductor IC device 100. The depicted fabrication operations of method 300 are illustratively depicted and described above with reference to one or more of FIG. 3 through FIG. 12 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with patterning active 2D material layers 108, and sacrificial layers 104 into layered rows 109. At block 304, method 300 may continue with forming sacrificial gate structures 130, with forming gate spacers 140, and with recessing the layered rows 109 into layered stacks 111. At block 306, method 300 may continue with indenting the sacrificial layers 104 and forming the inner spacers 154 within the indents.

At block 308, method 300 may continue with forming liner 160 layer and with forming the conductive contact 162 upon the liner 160 layer. At block 310, excess liner 160 layer material is removed to form the liner 160 around the conductive contact 162 and with forming the source/drain region 164 upon the conductive contact 162.

At block 312, method 300 may continue with forming ILD 168, with removing the sacrificial gate structure(s) 130, and with removing the sacrificial layers 104 to reveal active 2D material layers 108. At block 314, method 300 may continue with forming the replacement gate structure 170 around the active 2D material layers 108, with forming ILD 178, with forming frontside contact(s) 180, and with forming the frontside BEOL network 182. At block 316, method 300 may continue with removing the substrate structure 102, with forming backside ILD 190, with forming the backside contact opening 208 that removes a portion of the backside ILD 190 and a portion of the liner 160 that is around the bottom portion of the conductive contact 162 while the liner 160 that is around the top portion of the conductive contact 162 is retained. Further, at block 316, method 300 may continue with forming the backside contact(s) 210 and with forming the backside BEOL network 220.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a first conductive source/drain region connected to a second conductive source/drain region by a plurality of active two dimensional (2D) material channels;
a first conductive contact directly coupled to a bottom of the first conductive source/drain region;
a first liner directly coupled around an upper portion of the first conductive contact; and
a backside contact directly coupled to a lower portion of the first conductive contact.

2. The semiconductor IC device of claim 1, further comprising:
a second conductive contact directly coupled to a bottom of the second conductive source/drain region; and
a second liner directly coupled around a remaining perimeter of the second conductive contact.

3. The semiconductor IC device of claim 2, further comprising:
a backside interlayer dielectric (ILD) directly coupled to the first liner, to the backside contact, and to the second liner.

4. The semiconductor IC device of claim 3, further comprising:
a frontside contact directly coupled to the second conductive source/drain region.

5. The semiconductor IC device of claim 4, further comprising:
a gate structure directly coupled around the plurality of active 2D material channels.

6. The semiconductor IC device of claim 5, further comprising:
a bottom inner spacer directly coupled to the gate structure, to the first conductive source/drain region, and to the first liner.

7. The semiconductor IC device of claim 6, further comprising:
a frontside back end of line network that is connected to the frontside contact.

8. The semiconductor IC device of claim 7, further comprising:
a backside back end of line network that is connected to the backside contact.

9. The semiconductor IC device of claim 3, wherein a top surface of the first conductive contact is between a bottom surface of a bottommost active 2D material channel of the plurality of active 2D material channels and a top surface of the backside ILD.

10. The semiconductor IC device of claim 1, wherein the first conductive contact is composed of a first conductive material and wherein the first conductive source/drain region is composed of a second conductive material that is different from the first conductive material.

11. The semiconductor IC device of claim 1, wherein the first conductive contact and the first conductive source/drain region are composed of a substantially same conductive material and wherein there is an interfacial resistance between the first conductive contact and the first conductive source/drain region.

12. The semiconductor IC device of claim 1, wherein respective ends of the plurality of active 2D material channels are directly coupled to the first conductive source/drain region and distal respective ends of the plurality of active 2D material channels are directly coupled to the second conductive source/drain region.

13. The semiconductor IC device of claim 1, wherein a top surface of the first liner is substantially coplanar with a top surface of the first conductive contact.

14. The semiconductor IC device of claim 1, wherein the lower portion of the first conductive contact is inset within the backside contact.

15. A semiconductor integrated circuit (IC) device comprising:
a metallic source/drain region connected to a plurality of active two dimensional (2D) material channels;
a metallic contact directly coupled to a bottom of the metallic source/drain region;
a dielectric liner directly coupled around an upper portion of the metallic contact; and
a backside contact directly coupled to a lower portion of the metallic contact.

16. The semiconductor IC device of claim 15, further comprising:
a backside interlayer dielectric (ILD) directly coupled to the dielectric liner and to the backside contact.

17. The semiconductor IC device of claim 16, further comprising:
a gate structure directly coupled around the plurality of active 2D material channels.

18. The semiconductor IC device of claim 17, further comprising:
a bottom inner spacer directly coupled to the gate structure, to the first metallic source/drain region, and to the dielectric liner.

19. The semiconductor IC device of claim 18, further comprising:
a backside back end of line network that is connected to the backside contact.

20. A semiconductor integrated circuit (IC) device fabrication method comprising:
separating a layered row into multiple layered stacks and thereby expose an underlying substrate structure;
recessing the exposed substrate structure;
depositing a dielectric liner upon respective sidewalls of the multiple layered stacks and upon the recessed substrate structure;
forming a conductive contact upon the dielectric liner, wherein a top surface of the conductive contact is substantially coplanar with a top surface of the dielectric liner; and
forming a conductive source/drain region upon the top surface of the conductive contact and upon the top surface of the dielectric liner.
